(19) United States
(12) Patent Application Publication
(10) Pub. No.: US 2025/0374551 A1
(43) Pub. Date: Dec. 4, 2025

(54) Vertical Ferroelectric Transistor, Ferroelectric Memory Circuitry, And Method Used In Forming A Vertical Ferroelectric Transistor

(71) Applicant: Micron Technology, Inc., Boise, ID (US)

(72) Inventors: Jae Young Ahn, Boise, ID (US); Jin Yue, Boise, ID (US); Jae Kyu Choi, Boise, ID (US); Dmitry Mikulik, Meridian, ID (US)

(73) Assignee: Micron Technology, Inc., Boise, ID (US)

(21) Appl. No.: 19/190,059

(22) Filed: Apr. 25, 2025

Related U.S. Application Data
(60) Provisional application No. 63/653,373, filed on May 30, 2024.

(51) Int. Cl. H10B 51/30; H10B 51/10; H10B 51/20

(52) U.S. Cl. CPC H10B 51/30; H10B 51/10; H10B 51/20

(57) ABSTRACT

A vertical ferroelectric transistor comprises an upper source/drain region and a lower source/drain region having a channel region vertically there-between. A gate is laterally aside the channel region. Ferroelectric material is laterally aside and laterally between the gate and the channel region. Insulator material of different composition from that of the ferroelectric material is laterally aside and laterally between the gate and the ferroelectric material. The insulator material comprising (a) and (b) that are laterally aside one another and described herein. Ferroelectric memory and method are also disclosed.

### TECHNICAL FIELD

Embodiments disclosed herein pertain to vertical ferroelectric transistors, to ferroelectric memory circuitry, and to methods used in forming a vertical ferroelectric transistor.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, sense lines, or data/sense lines) and access lines (which may also be referred to as wordlines). The digitlines may conductively interconnect memory cells along columns of the array, and the access lines may conductively interconnect memory cells along rows of the array.

Memory cells may be volatile or nonvolatile. Nonvolatile memory cells can store data for extended periods of time including when the computer is turned off. Volatile memory dissipates and therefore requires being refreshed/rewritten, in many instances multiple times per second. Regardless, memory cells are configured to retain or store memory in at least two different selectable states. In a binary system, the states are considered as either a “0” or a “1”. In other systems, at least some individual memory cells may be configured to store more than two levels or states of information.

Ferroelectric field effect transistors (FeFET) may be used as memory cells. Specifically, the FeFETs may have two selectable memory states corresponding to two different polarization modes or states of ferroelectric material within the FeFETS. The different polarization modes may be characterized by, for example, different threshold voltages (Vt) or by different channel conductivities for a selected operating voltage. The ferroelectric polarization mode of a FeFET may remain in the absence of power (at least for a measurable duration).

One type of ferroelectric transistor is a metal-ferroelectric-metal-insulator-semiconductor (MFMIS) transistor. Such has a gate dielectric (insulator, I) between metal (M) and semiconductor material(S). Such also has ferroelectric (F) material over the metal, and has a gate (typically comprising metal, M) over the ferroelectric material. In operation, an electric field across the ferroelectric material is used to switch the ferroelectric material from one polarization mode or state to another. The ferroelectric transistor comprises a pair of source/drain regions having a channel region there-between. Conductivity across the channel region is influenced by the polarization mode/state of the ferroelectric material. Another type of ferroelectric transistor is metal-ferroelectric-insulator-semiconductor (M FIS) in which ferroelectric material directly touches the insulator (i.e., in which there is no intervening metal between the ferroelectric material and the insulator). Other types of ferroelectric transistors include metal-insulator-ferroelectric-insulator-semiconductor (MIFIS) and metal-insulator-ferroelectric-semiconductor (MIFS) constructions.

### BRIEF DESCRIPTION OF THE DRAWINGS

FIG. 1 is a diagrammatic view of a vertical ferroelectric transistor in accordance with an embodiment of the invention.

FIG. 2 is an enlarged view of a portion of FIG. 1.

FIG. 3 is a diagrammatic view of a vertical ferroelectric transistor in accordance with an embodiment of the invention.

FIG. 4 is a diagrammatic view of a vertical ferroelectric transistor in accordance with an embodiment of the invention.

FIG. 5 is a diagrammatic view of a vertical ferroelectric transistor in accordance with an embodiment of the invention.

FIGS. 6-10 show an example embodiment of ferroelectric memory circuitry in accordance with the invention.

FIG. 11 shows an example embodiment of ferroelectric memory circuitry in accordance with the invention.

FIG. 12 shows an example embodiment of ferroelectric memory circuitry in accordance with the invention.

FIG. 13 shows an example embodiment of ferroelectric memory circuitry in accordance with the invention.

FIG. 14 is a block diagram showing a method in accordance with an embodiment of the invention.

### DETAILED DESCRIPTION OF EXAMPLE EMBODIMENTS

Embodiments of the invention comprise a vertical ferroelectric transistor, ferroelectric memory circuitry, and a method used in forming a vertical ferroelectric transistor.

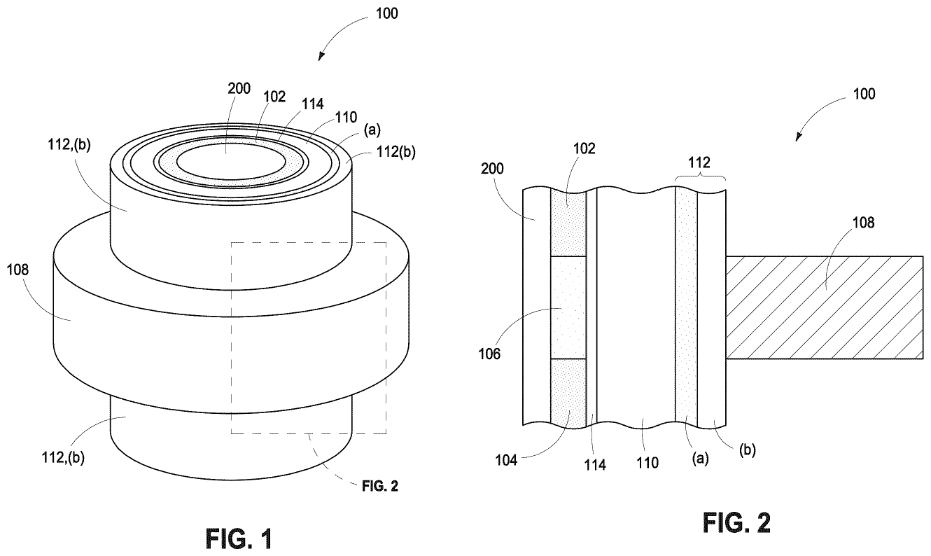

A first example structure embodiment comprising a vertical ferroelectric transistor 100 is described with reference to FIGS. 1 and 2. Such comprises an upper source/drain region 102 and a lower source/drain region 104 having a channel region 106 vertically there-between. A gate 108 is laterally aside channel region 106. Ferroelectric material 110 is laterally aside and laterally between gate 108 and channel region 106. Source/drain regions 102 and 104, by way of example only, may comprise crystalline semiconductive material that has been conductively-doped with a conductivity-enhancing impurity to be conductive. Channel region 106, by way of example only, may comprise appropriately-doped or undoped crystalline semiconductor material, such as one or more silicon, germanium, and so-called III/V semiconductor materials (e.g., GaAs, InP, GaP, and GaN). Ferroelectric material 110, by way of example only, may comprise a hafnium oxide or a titanium oxide additionally containing one or more of silicon, aluminum, barium, strontium, or zirconium. Gate 108 may be any suitable conductive material(s)(e.g., conductive metal material and/or conductively-doped semiconductive material).

Insulator material 112 of different composition from that of ferroelectric material 110 is laterally aside and laterally between gate 108 and ferroelectric material 110. Insulator material 112 comprises (a) and (b) that are laterally aside one another, where:
(a): at least one of (1) and (2), where:
   (1): MₓSiN_{y} where the “x” is 0.001 to 0.2, the “y” is 0.5 to 2.0, and the “M” is at least one of Sc, Y, Al, Ga, In Tl, Ge, Sn, Pb, or an element from IUPAC Groups 4, 5, 6, 7, 8, 9, 10, 11, and 12 of the periodic table; and
   (2): SiN_{z} where the “z” is 0.9 to 1.30; and
(b): insulating material of different composition from that of the (a) (e.g., silicon dioxide, stoichiometric or nitrogen-rich silicon nitride if (a) is (2), silicon oxynitride, and insulative metal oxides that are ideally not ferroelectric).

In one embodiment, insulator material 112 comprises the (1) and in some such embodiments the “x” is 0.002 to 0.05; the “y” is less than 1.33; the “y” is greater than 1.33; the “y” is equal to 1.33; the “M” is only one of Sc, Y, Al, Ga, In Tl, Ge, Sn, Pb, or an element from IUPAC Groups 4, 5, 6, 7, 8, 9, 10, 11, and 12 of the periodic table; the M is more than one of Sc, Y, Al, Ga, In Tl, Ge, Sn, Pb, or an element from IUPAC Groups 4, 5, 6, 7, 8, 9, 10, 11, and 12 of the periodic table; the M is at least Hf; and the M is at least Al. In one embodiment, insulator material 112 comprises the (2) and in one such embodiment the “z” is 0.9 to 1.3. In one embodiment, insulator material 112 and ferroelectric material 110 are directly against one another. An example thickness for each of the (a) and (b) is 10 Angstrom to 90 Angstroms, with an example total thickness of both together being 20 Angstroms to 100 Angstroms.

In one embodiment and as shown, ferroelectric material 110 is not directly against channel region 106. In one such embodiment, an insulative material 114 of different composition from that of ferroelectric material 110 and that of the (1) is laterally aside and laterally between ferroelectric material 110 and channel region 106. In some such latter embodiments, insulative material 114 is of different composition from that of the (2) and/or the (b) and insulative material 114 and the (b) are of the same composition relative one another. Regardless, example vertical ferroelectric transistor 100 as shown may be considered as being of a metal-insulator-ferroelectric-insulator-semiconductor (MIFIS) construction.

A solid insulative core 200 (e.g., silicon dioxide and/or silicon nitride) may be radially inside of channel region 106. Features 102, 104, 106, 108, 110, 112, (a), (b), 114, and 200 by way of example only are shown as being circular in horizontal cross-section and being cylindrical. Other shapes and configurations may of course be used. Further, features 200, 114, 110, 112, (a), and (b) are optionally shown as extending to above and/or below gate 108.

Any other attribute(s) or aspect(s) as shown and/or described herein with respect to other embodiments may be used in the embodiments shown and described with reference to the above embodiments.

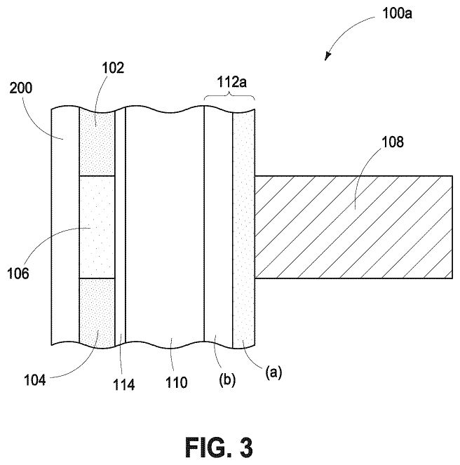

FIGS. 3-5 show alternate embodiment vertical ferroelectric transistors 100a, 100b, and 100c. Like numerals from the above-described embodiments have been used where appropriate, with some construction differences being indicated with the suffixes “a”, “b”, and “c”, respectively, or with different numerals.

In vertical ferroelectric transistor 100 in FIGS. 1 and 2, the (b) is closer to gate 108 than is the (a). In some such embodiments, the (b) is directly against gate 108 and/or the (a) is directly against ferroelectric material 110. In vertical ferroelectric transistor 100a in FIG. 3, the (a) is closer to gate 108 than is the (b). In some such embodiments, the (a) is directly against gate 108 and/or the (b) is directly against ferroelectric material 110. Any other attribute(s) or aspect(s) as shown and/or described herein with respect to other embodiments may be used.

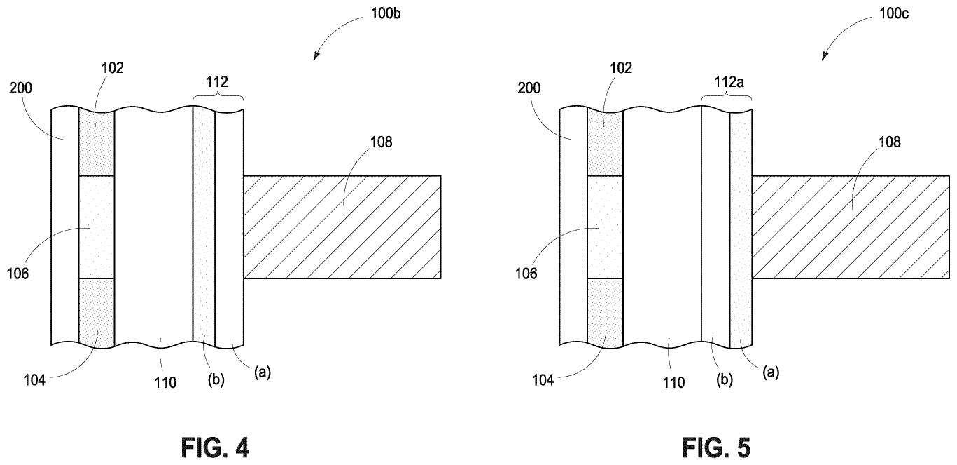

In vertical ferroelectric transistor 100 in FIGS. 1 and 2, ferroelectric material 110 is not directly against channel region 106. FIGS. 4 and 5 correspond to FIGS. 2 and 3, respectively, and wherein in vertical ferroelectric transistors 100b and 100c, ferroelectric material 110 is directly against channel region 106 (e.g., insulative material 114 [not shown] of FIGS. 1 and 2 is not present). Example vertical ferroelectric transistors 100b and 100c as shown may be considered as being of a metal-insulator-ferroelectric-semiconductor (MIFS) construction. Any other attribute(s) or aspect(s) as shown and/or described herein with respect to other embodiments may be used.

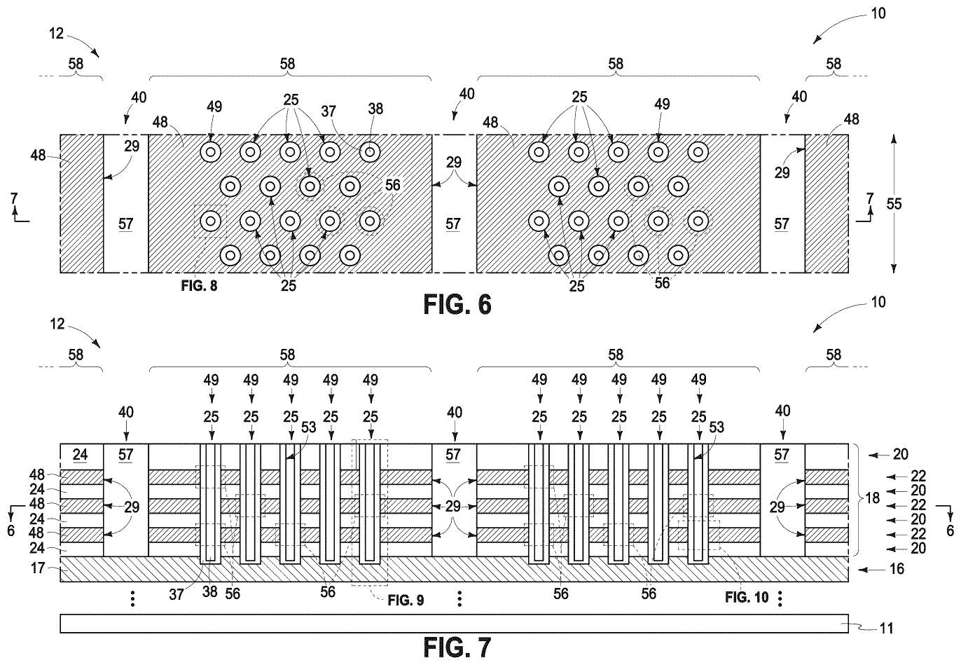

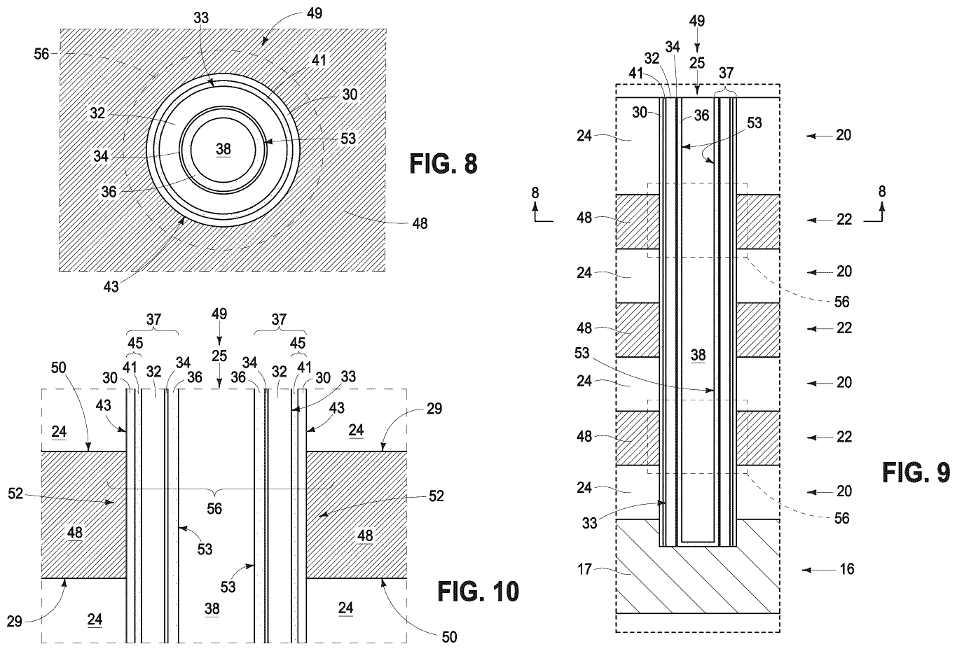

Embodiments of the invention comprise ferroelectric memory circuitry, for example as shown in FIGS. 6-10, and for example including an array of ferroelectric NAND or other ferroelectric memory cells having peripheral control circuitry under the array (e.g., CMOS-under-array).

FIGS. 6-10 show a construction 10 comprising a memory array 12. Example construction 10 comprises a base substrate 11 comprising conductive/conductor/conducting, semiconductive/semiconductor/semiconducting, and/or insulative/insulator/insulating (i.e., electrically herein) materials. Various materials have been formed elevationally over base substrate 11. Materials may be aside, elevationally inward, or elevationally outward of the FIGS. 6-10-depicted materials. For example, other partially or wholly fabricated components of integrated circuitry may be provided somewhere above, about, or within base substrate 11. Control and/or other peripheral circuitry for operating components within an array (e.g., memory array 12) of elevationally-extending strings of memory cells may also be fabricated and may or may not be wholly or partially within an array or sub-array. Further, multiple sub-arrays may also be fabricated and operated independently, in tandem, or otherwise relative one another. In this document, a “sub-array” may also be considered as an array.

A conductor tier 16 comprising conductor material 17 (e.g., WSiₓ under conductively-doped polysilicon) is above substrate 11. Conductor tier 16 may comprise part of control circuitry (e.g., peripheral-under-array circuitry and/or a common source line or plate) used to control read and write access to the ferroelectric transistors and/or ferroelectric memory cells 56 in array 12. A stack 18 comprising vertically-alternating insulative tiers 20 and conductive tiers 22 is directly above conductor tier 16. Example thickness for each of tiers 20 and 22 is 20 to 60 nanometers. The example uppermost tier 20 may be thicker/thickest compared to one or more other tiers 20 and/or 22. Only a small number of tiers 20 and 22 is shown in FIGS. 6-10, with more likely stack 18 comprising dozens, a hundred or more, etc. of tiers 20 and 22. Other circuitry that may or may not be part of peripheral and/or control circuitry may be between conductor tier 16 and stack 18. For example, multiple vertically-alternating tiers of conductive material and insulative material of such circuitry may be below a lowest of the conductive tiers 22 and/or above an uppermost of the conductive tiers 22. For example, one or more select gate tiers (not shown) may be between conductor tier 16 and the lowest conductive tier 22 and one or more select gate tiers may be above an uppermost of conductive tiers 22 (not shown). Alternately or additionally, at least one of the depicted uppermost and lowest conductive tiers 22 may be a select gate tier. Example insulative tiers 20 comprise insulative material 24 (e.g., silicon dioxide and/or other material that may be of one or more composition(s)).

Channel openings 25 have been formed (e.g., by etching) through insulative tiers 20 and conductive tiers 22 to conductor tier 16. Channel openings 25 may taper radially-inward (not shown) moving deeper in stack 18. In some embodiments, channel openings 25 may go into conductor material 17 of conductor tier 16 as shown or may stop there-atop (not shown). Alternately, as an example, channel openings 25 may stop atop or within the lowest insulative tier 20. A reason for extending channel openings 25 at least to conductor material 17 of conductor tier 16 is to assure direct electrical coupling of channel material to conductor tier 16 without using alternative processing and structure to do so when such a connection is desired. Etch-stop material (not shown) may be within or atop conductor material 17 of conductor tier 16 to facilitate stopping of the etching of channel openings 25 relative to conductor tier 16 when such is desired. Such etch-stop material may be sacrificial or non-sacrificial. By way of example and for brevity only, channel openings 25 are shown as being arranged in groups or columns of staggered rows of four and five openings 25 per row and being arrayed in laterally-spaced memory blocks 58. In this document, “block” is generic to include “sub-block”. Memory blocks 58 may be considered as being longitudinally elongated and oriented, for example along a first direction 55. Any alternate existing or future-developed arrangement and construction may be used.

Example memory blocks 58 are shown as at least in part having been defined by horizontally-elongated trenches 40 that were formed (e.g., by anisotropic etching) into stack 18 (e.g., trenches 40 being between immediately-laterally-adjacent memory blocks 58). Trenches 40 will typically be wider than channel openings 25 (e.g., 3 to 10 times wider). Trenches 40 may have respective bottoms that are directly against conductor material 17 (e.g., atop or within) of conductor tier 16 (as shown) or may have respective bottoms that are above conductor material 17 of conductor tier 16 (not shown). Trenches 40 may taper laterally inward and/or outward in vertical cross-section (not shown). Example intervening material 57 (e.g., silicon dioxide and/or silicon nitride) is in trenches 40 and may include through-array-vias (not shown) extending therethrough.

Channel material 36 is in channel openings 25 elevationally along insulative tiers 20 and conductive tiers 22 and comprise individual operative channel-material strings 53 (extending through tiers 20 and 22) with material 24 in insulative tiers being 20 horizontally-between immediately-adjacent channel-material strings 53. Channel material may comprise any of the attributes described above with respect to channel region 106.

Individual conductive tiers 22 comprise access lines 29 (e.g., wordlines) that comprise a gate 52 (e.g., 108 in the first-described embodiments) of individual ferroelectric memory cells 56 of the ferroelectric memory circuitry. Access lines 29 comprise conductive material 48 (e.g., conductive metal material, e.g., containing molybdenum). Conductive lines 29 comprise part of elevationally-extending strings 49 of individual ferroelectric transistors and/or ferroelectric memory cells 56. A thin insulative liner (e.g., Al₂O₃ and not shown) may be formed before forming conductive material 48. Approximate locations of some transistors and/or some memory cells 56 are indicated with a bracket or with dashed outlines, with transistors and/or memory cells 56 being essentially ring-like or annular in the depicted example. Alternately, transistors and/or memory cells 56 may not be completely encircling relative to individual channel openings 25 such that each channel opening 25 may have two or more elevationally-extending strings 49 (e.g., multiple transistors and/or memory cells about individual channel openings in individual conductive tiers with perhaps multiple wordlines per channel opening in individual conductive tiers, and not shown). Conductive material 48 may be considered as having terminal ends 50 corresponding to control-gate regions 52 of individual transistors and/or memory cells 56. Control-gate regions 52 in the depicted embodiment comprise individual portions of individual conductive lines 29.

Individual ferroelectric memory cells 56 comprise a portion of individual channel-material strings 53 that is in one of individual conductive tiers 22. Memory cells 56 also individually comprise ferroelectric material 32 (e.g., same as ferroelectric material 110 in the above-described embodiments) that is laterally aside and laterally between gate 52/48 and the portion of the individual channel-material string 53. In one embodiment and as shown, ferroelectric material 32 is part of one of a plurality of ferroelectric-material strings 33 that extend through insulative tiers 20 and conductive tiers 22.

Memory cells 56 also individually comprise insulator material 45 (e.g., same as insulator material 112 in the above-described embodiments) of different composition from that of ferroelectric material 32 laterally aside and laterally between gate 52/48 and ferroelectric material 32. In one embodiment and as shown, ferroelectric material 32 is not directly against channel material 36, for example having an insulative material 34 (same properties as insulative material 114 described above; e.g., MIFIS) laterally aside and laterally between ferroelectric material 32 and channel material 36. In one embodiment, insulator material 45 is part of one of a plurality of insulator-material strings 43 that extend through insulative tiers 20 and conductive tiers 22. Regardless, insulator material 45 comprises the (a)(now designated as 41) and the (b)(now designated as 30) as described in the above embodiments, with the (a) and the (b) being laterally aside one another. Materials 30, 41, 32, 34, and 36 are collectively shown as, and only designated as, material 37 in some figures due to scale.

Punch etching may be conducted as shown to remove materials 30, 41, 32, and 34 from the bases of channel openings 25 to expose conductor tier 16 such that channel material 36 (operative channel-material string 53) is directly electrically coupled with conductor material 17 of conductor tier 16. Such punch etching may occur separately with respect to each of materials 30, 32, and 34 (as shown) or may occur collectively with respect to all after deposition of material 34 (not shown). Alternately, and by way of example only, no punch etching may be conducted and channel material 36 may be directly electrically coupled with conductor material 17 of conductor tier 16 by a separate conductive interconnect (not shown). Channel openings 25 are shown as comprising a radially-central solid dielectric material 38 (e.g., spin-on-dielectric, silicon dioxide, and/or silicon nitride). Alternately, and by way of example only, the radially-central portion within channel openings 25 may include void space(s) (not shown) and/or be devoid of solid material (not shown).

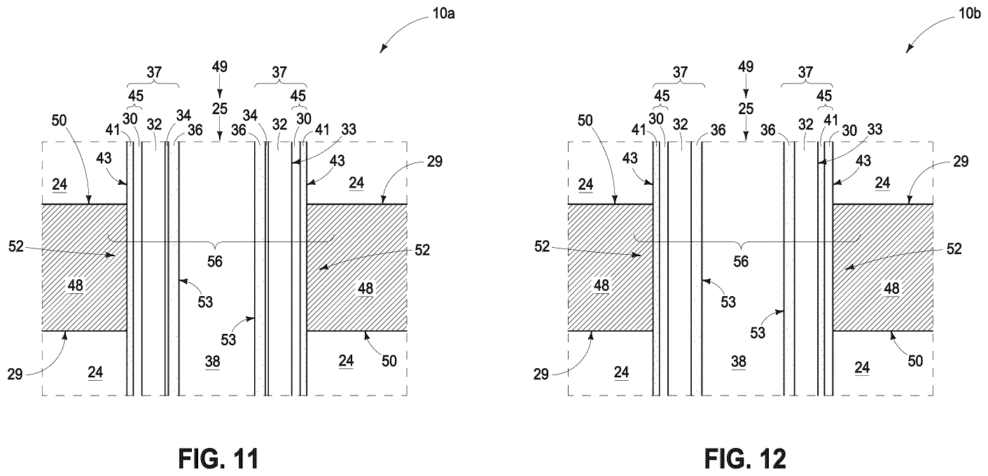

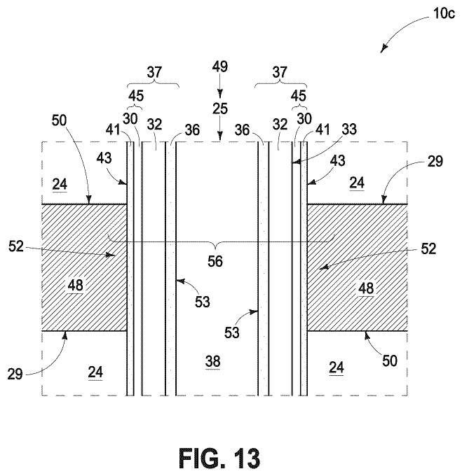

Any of the attributes described above with respect to transistors 100, 100a, 100b, and 100c may be used/apply with respect to transistors/memory cells 56, for example as shown in FIGS. 11, 12, and 13 with respect to constructions 10a, 10b, and 10c, respectively (corresponding to FIG. 10 with respect to construction 10).

Embodiments of the invention encompass methods used in forming a vertical ferroelectric transistor that by way of example only may incorporate device/structure as referred to above, including that of ferroelectric memory circuitry as referred to above. Nevertheless, the method embodiments may or may not incorporate, form, and/or have any of the attributes described with respect to device embodiments.

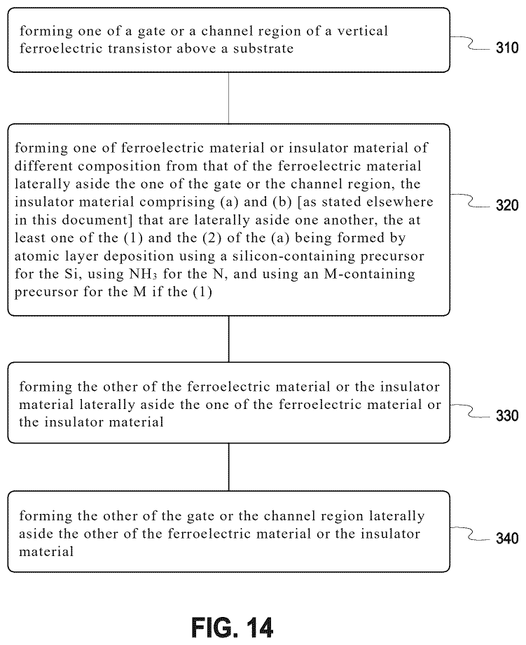

In one embodiment, and referring to FIG. 14 and FIGS. 1-13, a method used in forming a vertical ferroelectric transistor (e.g., 100, 100a, 100b, 100c, 56) comprises forming one of a gate (e.g., 108, 52) or a channel region (e.g., 106, 36) of a vertical ferroelectric transistor above a substrate (e.g., such method exemplified in part by box 310). One of ferroelectric material (e.g., 110, 32) or insulator material (e.g., 112, 45) of different composition from that of the ferroelectric material is formed laterally aside the one of the gate or the channel region (e.g., box 320). The insulator material comprises the (a) and the (b) as described above and that are laterally aside one another. The at least one of the (1) and the (2) of the (a) is formed by atomic layer deposition using a silicon-containing precursor (e.g., a silane) for the Si, using NH₃ for the N, and using an M-containing precursor for the M if the (1)(e.g., germanium (II) chloride dioxane (C₄H₈Cl₂GeO₂) for Ge, TiCl₄ for Ti, vanadyl acetylacetonate for V, tetrakis(ethylmethylamido) hafnium (IV)(Hf[N(CH₃)(C₂H₅)]₄ for Hf, and tetrakis(ethylmethylamido) zirconium (IV), Zr[N(CH₃)(C₂H₅)]₄ for Zr). The other of the ferroelectric material or the insulator material is formed laterally aside the one of the ferroelectric material or the insulator material (e.g., box 330). The other of the gate or the channel region is formed laterally aside the other of the ferroelectric material or the insulator material (e.g., box 340).

In one embodiment, the atomic layer deposition using the silicon-containing precursor, the NH₃, and the M-containing precursor if the (1) is conducted in a vacuum chamber without breaking vacuum and without removing the substrate from the vacuum chamber between atomic layer deposition steps. In one such latter embodiment, the ferroelectric material is formed by atomic layer deposition in the vacuum chamber without breaking the vacuum and without removing the substrate from the vacuum chamber between the atomic layer deposition of the insulator material and the atomic layer deposition of the ferroelectric material.

The conditions for such atomic layer deposition are not material to the invention and the artisan is capable of selecting same.

Any other attribute(s) or aspect(s) as shown and/or described herein with respect to other embodiments may be used.

Use of an example insulator material 45, 112 as described herein may, although not require, improve memory window and retention in vertical ferroelectric memory cells as described herein as compared to prior art constructions.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a vertical ferroelectric transistor comprises an upper source/drain region and a lower source/drain region having a channel region vertically there-between. A gate is laterally aside the channel region. Ferroelectric material is laterally aside and laterally between the gate and the channel region. Insulator material of different composition from that of the ferroelectric material is laterally aside and laterally between the gate and the ferroelectric material. The insulator material comprises (a) and (b) that are laterally aside one another, where:
(a): at least one of (1) and (2), where:
   (1): MₓSiN_{y} where the “x” is 0.001 to 0.2, the “y” is 0.5 to 2.0, and the “M” is at least one of Sc, Y, Al, Ga, In Tl, Ge, Sn, Pb, or an element from IUPAC Groups 4, 5, 6, 7, 8, 9, 10, 11, and 12 of the periodic table; and
   (2): SiN_{z} where the “z” is 0.9 to 1.30; and
(b): insulating material of different composition from that of the (a).

In some embodiments, ferroelectric memory circuitry comprises a stack comprising vertically-alternating insulative tiers and conductive tiers. Channel-material strings extend through the insulative tiers and the conductive tiers. Individual of the conductive tiers comprise access lines that comprise a gate of individual ferroelectric memory cells of the memory circuitry. The individual ferroelectric memory cells comprise a portion of individual of the channel-material strings that is in one of the individual conductive tiers. Ferroelectric material is laterally aside and laterally between the gate and the portion of the individual channel-material string. Insulator material of different composition from that of the ferroelectric material is laterally aside and laterally between the gate and the ferroelectric material. The insulator material comprising (a) and (b) that are laterally aside one another, where:
(a): at least one of (1) and (2), where:
   (1): MₓSiN_{y} where “x” is 0.001 to 0.2, “y” is 0.5 to 2.0, and “M” is at least one of Sc, Y, Al, Ga, In Tl, Ge, Sn, Pb, or an element from IUPAC Groups 4, 5, 6, 7, 8, 9, 10, 11, and 12 of the periodic table; and
   (2): SiN_{z} where “z” is 0.9 to 1.30; and
(b): insulating material of different composition from of that of the (a).

In some embodiments, a method used in forming a vertical ferroelectric transistor comprises forming one of a gate or a channel region of a vertical ferroelectric transistor above a substrate. One of ferroelectric material or insulator material of different composition is formed from that of the ferroelectric material laterally aside the one of the gate or the channel region. The insulator material comprises (a) and (b) that are laterally aside one another, where:
(a): at least one of (1) and (2), where:
   (1): MₓSiN_{y} where “x” is 0.001 to 0.2, “y” is 0.5 to 2.0, and “M” is at least one of Sc, Y, Al, Ga, In Tl, Ge, Sn, Pb, or an element from IUPAC Groups 4, 5, 6, 7, 8, 9, 10, 11, and 12 of the periodic table; and
   (2) SiN_{z} where “z” is 0.9 to 1.30; and
(b): insulating material of different composition from that of the (a).

The at least one of the (1) and the (2) are formed by atomic layer deposition using a silicon-containing precursor for the Si, using NH₃ for the N, and using an M-containing precursor for the M if the (1). The other of the ferroelectric material or the insulator material is formed laterally aside the one of the ferroelectric material or the insulator material. The other of the gate or the channel region is formed laterally aside the other of the ferroelectric material or the insulator material.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A vertical ferroelectric transistor comprising:
an upper source/drain region and a lower source/drain region having a channel region vertically there-between;
a gate laterally aside the channel region;
ferroelectric material laterally aside and laterally between the gate and the channel region; and
insulator material of different composition from that of the ferroelectric material laterally aside and laterally between the gate and the ferroelectric material, the insulator material comprising (a) and (b) that are laterally aside one another, where:
(a): at least one of (1) and (2), where:
(1): MₓSiN_{y} where the “x” is 0.001 to 0.2, the “y” is 0.5 to 2.0, and the “M” is at least one of Sc, Y, Al, Ga, In Tl, Ge, Sn, Pb, or an element from IUPAC Groups 4, 5, 6, 7, 8, 9, 10, 11, and 12 of the periodic table; and
(2): SiN_{z} where the “z” is 0.9 to 1.30; and (2):
(b): insulating material of different composition from that of the (a).

2. The vertical ferroelectric transistor of claim 1 comprising the (1).

3. The vertical ferroelectric transistor of claim 2 wherein the “x” is 0.002 to 0.05.

4. The vertical ferroelectric transistor of claim 2 wherein the “y” is less than 1.33.

5. The vertical ferroelectric transistor of claim 2 wherein the “y” is greater than 1.33.

6. The vertical ferroelectric transistor of claim 2 wherein the “y” is 1.33.

7. The vertical ferroelectric transistor of claim 2 wherein the M is only one of Sc, Y, Al, Ga, In Tl, Ge, Sn, Pb, or an element from IUPAC Groups 4, 5, 6, 7, 8, 9, 10, 11, and 12 of the periodic table.

8. The vertical ferroelectric transistor of claim 2 wherein the M is more than one of Sc, Y, Al, Ga, In Tl, Ge, Sn, Pb, or an element from IUPAC Groups 4, 5, 6, 7, 8, 9, 10, 11, and 12 of the periodic table.

9. The vertical ferroelectric transistor of claim 2 wherein the M is at least Hf.

10. The vertical ferroelectric transistor of claim 2 wherein the M is at least Al.

11. The vertical ferroelectric transistor of claim 1 comprising the (2).

12. The vertical ferroelectric transistor of claim 1 wherein the insulator material and the ferroelectric material are directly against one another.

13. The vertical ferroelectric transistor of claim 1 wherein the (b) is closer to the gate than is the (a).

14. The vertical ferroelectric transistor of claim 1 wherein the (a) is closer to the gate than is the (b).

15. The vertical ferroelectric transistor of claim 1 wherein the ferroelectric material is directly against the channel region.

16. The vertical ferroelectric transistor of claim 1 wherein the ferroelectric material is not directly against the channel region.

17. Ferroelectric memory circuitry comprising:
a stack comprising vertically-alternating insulative tiers and conductive tiers, channel-material strings extending through the insulative tiers and the conductive tiers,
individual of the conductive tiers comprising access lines that comprise a gate of individual ferroelectric memory cells of the memory circuitry; and
the individual ferroelectric memory cells comprising:
a portion of individual of the channel-material strings that is in one of the individual conductive tiers;
ferroelectric material that is laterally aside and laterally between the gate and the portion of the individual channel-material string;
insulator material of different composition from that of the ferroelectric material laterally aside and laterally between the gate and the ferroelectric material, the insulator material comprising (a) and (b) that are laterally aside one another, where:
(a): at least one of (1) and (2), where:
(1): MₓSiN_{y} where “x” is 0.001 to 0.2, “y” is 0.5 to 2.0, and “M” is at least one of Sc, Y, Al, Ga, In Tl, Ge, Sn, Pb, or an element from IUPAC Groups 4, 5, 6, 7, 8, 9, 10, 11, and 12 of the periodic table; and
(2): SiN_{z} where “z” is 0.9 to 1.30; and
(b): insulating material of different composition from of that of the (a).

18. The ferroelectric memory circuitry 25 wherein the ferroelectric material is part of one of a plurality of ferroelectric-material strings that extend through the insulative tiers and the conductive tiers.

19. The ferroelectric memory circuitry 25 of wherein the insulator material is part of one of a plurality of insulator-material strings that extend through the insulative tiers and the conductive tiers.

20. A method used in forming a vertical ferroelectric transistor, comprising:
forming one of a gate or a channel region of a vertical ferroelectric transistor above a substrate;
forming one of ferroelectric material or insulator material of different composition from that of the ferroelectric material laterally aside the one of the gate or the channel region, the insulator material comprising (a) and (b) that are laterally aside one another, where:
(a): at least one of (1) and (2), where:
(1): MₓSiN_{y} where “x” is 0.001 to 0.2, “y” is 0.5 to 2.0, and “M” is at least one of Sc, Y, Al, Ga, In Tl, Ge, Sn, Pb, or an element from IUPAC Groups 4, 5, 6, 7, 8, 9, 10, 11, and 12 of the periodic table; and
(2): SiN_{z} where “z” is 0.9 to 1.30; and
(b): insulating material of different composition from that of the (a);
the at least one of the (1) and the (2) being formed by atomic layer deposition using a silicon-containing precursor for the Si, using NH₃ for the N, and using an M-containing precursor for the M if the (1);
forming the other of the ferroelectric material or the insulator material laterally aside the one of the ferroelectric material or the insulator material; and
forming the other of the gate or the channel region laterally aside the other of the ferroelectric material or the insulator material.
